(19) United States
(12) Patent Application Publication
(10) Pub. No.: US 2013/0344268 A1
(43) Pub. Date: Dec. 26, 2013

(54) MOULDED ARTICLE AND LABEL THEREFOR

(71) Applicant: Alfred CHOI, Wong Chuk Hang (HK)

(72) Inventor: Alfred CHOI, Wong Chuk Hang (HK)

(21) Appl. No.: 13/532,954

(22) Filed: Jun. 26, 2012

(51) Int. Cl. B32B 1/08; C23C 16/06; B29C 65/48; B32B 33/00; B32B 15/085; B32B 15/095; B32B 15/09; B29C 45/14; B32B 27/06

(52) U.S. Cl. 428/35.9; 264/279; 427/250; 156/324; 156/272.6; 156/229; 428/457; 428/209; 428/461; 428/458

(57) ABSTRACT

The invention provides an in mould label for injection moulding that comprises a vacuum metallised layer of metal for creating a barrier to oxygen ingress. The invention further provides a moulded article including such an in-mould label, as well as a method of manufacture of such an article.

### FIELD OF THE INVENTION

The present invention relates to a moulded article. More particularly but not exclusively it relates to an injection moulded article having a label.

### BACKGROUND TO THE INVENTION

Currently the practice of labelling a moulded article by using an “in mould” label that is integrally formed with the moulded article is known.

Such labels are typically produced as a plastic sheet. The plastic sheet is then inserted into an injection moulding mechanism, and molten thermo plastic is injected into a cavity around the label to produce an article that includes an integrally formed label.

One disadvantage of currently moulded articles is the level of porosity that the moulded articles have to oxygen. Plastic materials have a natural porosity that allows oxygen to move through the plastic and into the contents of the moulded article.

One solution to this porosity problem used by moulders is to provide a barrier material that is co-extruded or provided as an additive to the plastic sheet that reduces the porosity to Oxygen of the plastic. One such barrier is ethylene vinyl alcohol polymer (EVOH).

Packaging products having a metallic appearance are typically produced by printing on a label with metallic coloured ink, by hot stamping or cold stamping. Metallic coloured inks can fade over time. Hot stamping and/or cold stamping processes utilise a metal foil that is applied by pressure and heat, typically in a laminate form, to a surface. However, such hot and cold stamping can be complex, expensive, and require specialised equipment.

In this specification, where reference has been made to external sources of information, including patent specifications and other documents, this is generally for the purpose of providing a context for discussing the features of the present invention. Unless stated otherwise, reference to such sources of information is not to be construed, in any jurisdiction, as an admission that such sources of information are prior art or form part of the common general knowledge in the art.

For the purposes of this specification, the term “plastic” shall be construed to mean a general term for a wide range of synthetic or semisynthetic polymerization products, and generally consisting of a hydrocarbon-based polymer.

For the purpose of this specification, where method steps are described in sequence, the sequence does not necessarily mean that the steps are to be chronologically ordered in that sequence, unless there is no other logical manner of interpreting the sequence.

It is an object of the present invention to provide a moulded article and process which overcomes or at least partially ameliorates some of the abovementioned disadvantages or which at least provides the public with a useful choice.

### SUMMARY OF THE INVENTION

In one aspect the present invention may be said to broadly consist in a moulded article, said moulded article comprising
a moulded body; and
a label, said label comprising
   a polymeric base layer, and
   a layer of metal that has been deposited on the polymeric base layer by vacuum metallising;
wherein said label is integrally formed with the moulded body.

In one embodiment, the layer of metal has a layer of ink on it.

In one embodiment, the layer of ink is printed on it.

In one embodiment, the layer of ink is digitally printed on it in a digitally controlled printing process.

In one embodiment, the label further comprises at least one or more plastic laminate layers.

In one embodiment, the label comprises a plastic laminate layer to either side of said polymeric base layer and layer of metal.

In one embodiment, at least one or more of the plastic laminate layers are composed of
polypropylene

In one embodiment, at least one or more of the plastic laminate layers are composed of one or more selected from:
casted polypropylene (CPP)
polyethylene terephthalate (PET)
biaxially oriented Polypropylene (BOPP).

In one embodiment, the polymeric base layer is one or more selected from
polyethylene terephthalate (PET);
polypropylene (PP)
nylon;
polyethylene (PE); and
any other suitable material.

In one embodiment, the metal is one or more selected from
aluminium;
copper;
platinum;
titanium;
chromium;
titanium;
gold;
lead;
nickel;
silver;
tin; and
tantalum.

In another aspect the present invention may be said to broadly consist in a method of producing a moulded article, said method comprising the steps of
providing a label, said label comprising
   at least a polymeric base layer, and
   a layer of metal that has been deposited on the polymer base sheet by vacuum metallising;
inserting the label into a mould cavity in a mould; and
moulding a moulded body with the label.

In one embodiment, the mould is an injection moulding mould, and the step of moulding comprises the step of injecting molten thermoplastic into the mould cavity to mould the moulded body with the label.

In one embodiment, the moulded article is a tube.

In one embodiment, the moulded article is a tube used for packaging.

In one embodiment, the moulded article is a tube used for packaging of matter that degrades on exposure to oxygen.

In one embodiment, the method includes the step of depositing vaporised metal on at least one major surface of the polymer sheet.

In one embodiment, the step of providing a label comprises the step of providing a polymer sheet.

In one embodiment, the step of providing a label comprises the step of inserting the polymer sheet into a vacuum chamber.

In one embodiment, the step of providing a label comprises the step of subjecting the polymer sheet to a reduced-pressure environment.

In one embodiment, the step of providing a label comprises the step of vaporising metal for deposition on the polymer sheet.

In one embodiment, the step of providing a label comprises the step of subjecting the polymer sheet to the vaporised metal for the vaporised metal to condense on and attach to the polymer sheet, to form a metallised sheet.

In one embodiment, the step of providing a label comprises the step of printing on the metallised sheet.

In one embodiment, the step of providing a label comprises the step of laminating at least the polymer sheet with one or more plastic layers to form a laminated label.

In one embodiment, the step of laminating the polymer sheet with one or more plastic layers comprises the step of treating at least part of the surface of one or more selected from the plastic layers and the polymer sheet by means of a Corona surface treatment.

In one embodiment, the step of laminating the polymer sheet with at least one or more plastic layers comprises the step of providing a plastic sheet to either side of the metallised sheet and laminating the plastic sheets and polymer sheet together.

In one embodiment, the step of laminating the metallised sheet with one or more plastic layers comprises the step of adhering at least one plastic laminate layer with one or more selected from another plastic laminate layer and the polymer sheet.

In one embodiment, the step of laminating the metallised sheet with one or more plastic layers comprises the step of adhering at least one of the plastic laminate layers with the metallised sheet.

In one embodiment, the method comprises the step of curing the laminated label.

In one embodiment, the step of curing the laminated labels comprises the step of subjecting the adhered label to one or more selected from:
an increased temperature;
a drying effect;
radiation;
or any other suitable curing effect.

In one embodiment, the step of curing the adhered labels comprising curing the label for a period of between 1 and 10 days.

In one embodiment, the layer of metal has a layer of ink on it.

In one embodiment, the layer of ink is printed on the layer of metal.

In one embodiment, the layer of ink is digitally printed on it in a digitally controlled printing process.

In one embodiment, the label further comprises at least one or more plastic laminate layers.

In one embodiment, the label comprises a plastic laminate layer to either side of said polymeric base layer and layer of metal.

In one embodiment, at least one or more of the plastic laminate layers are composed of
polypropylene

In one embodiment, at least one or more of the plastic laminate layers are composed of one or more selected from:
casted polypropylene (CPP)
polyethylene terephthalate (PET)
biaxially oriented Polypropylene (BOPP).

In one embodiment, the polymeric base layer is composed of one or more selected from
polyethylene terephthalate (PET);
polypropylene (PP)
nylon;
polyethylene (PE); and
any other suitable material.

In one embodiment, the metal of the metal layer is one or more selected from
aluminium;
copper;
platinum;
titanium;
chromium;
titanium;
gold;
lead;
nickel;
silver;
tin; and
tantalum.

In another aspect the present invention may be said to broadly consist in a label for insertion into a mould for being integrally formed with a moulded body to form a moulded article, said moulded article comprising
a polymeric base layer; and
a layer of metal that has been deposited on the polymeric base layer by vacuum metallisation;
wherein the label is configured and adapted for being inserted into a mould cavity, and integrally formed with a moulded body to form a moulded article.

In one embodiment, the label comprises at least one plastic laminate layer.

In one embodiment, the label comprises a plurality of plastic laminate layers.

In one embodiment, the label comprises a plastic laminate layer on opposed sides of the layer of metal and the polymeric base layer

In one embodiment, the plastic laminate layers are adhered to at least one selected from the layer of metal and the polymeric base layer by an adhesive.

In one embodiment, the label comprises a layer of ink that has been deposited on at least part of the layer of metal.

In one embodiment, the label comprises a fastening layer for fastening the layer of ink to the layer of metal.

In one embodiment, the fastening layer is a varnish layer.

In one embodiment, at least one or more of the plastic laminate layers are composed of
polypropylene

In one embodiment, at least one or more of the plastic laminate layers are composed of one or more selected from:
casted polypropylene (CPP)
polyethylene terephthalate (PET)
biaxially oriented Polypropylene (BOPP).

In one embodiment, the polymeric base layer is composed of one or more selected from
polyethylene terephthalate (PET);
polypropylene (PP)
nylon;
polyethylene (PE); and
any other suitable material.

In one embodiment, the metal of the metal layer is one or more selected from
aluminium;
copper;
platinum;
titanium;
chromium;
titanium;
gold;
lead;
nickel;
silver;
tin; and
tantalum.

In one embodiment, the mould cavity is for is an injection moulding mould.

Other aspects of the invention may become apparent from the following description which is given by way of example only and with reference to the accompanying drawings.

As used herein the term “and/or” means “and” or “or”, or both.

As used herein “(s)” following a noun means the plural and/or singular forms of the noun.

The term “comprising” as used in this specification and claims means “consisting at least in part of”. When interpreting statements in this specification and claims which include that term, the features, prefaced by that term in each statement, all need to be present but other features can also be present. Related terms such as “comprise” and “comprised” are to be interpreted in the same manner.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

### BRIEF DESCRIPTION OF THE DRAWINGS

The invention will now be described by way of example only and with reference to the drawings in which:

FIG. 1: shows a cutaway perspective view of a moulded tube;

FIG. 2: shows a schematic side view of a label;

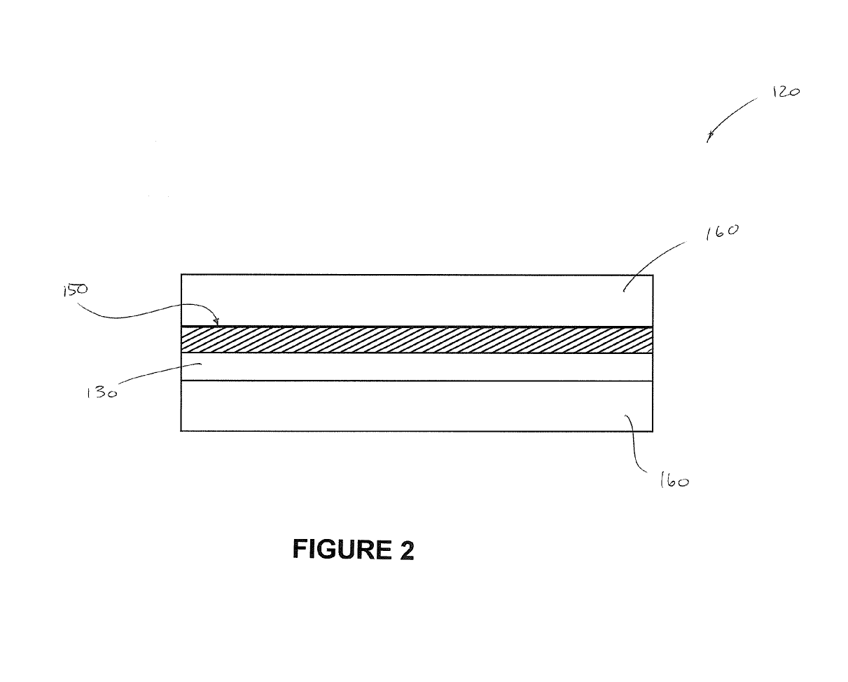

FIG. 3: shows a schematic side view of a label; and

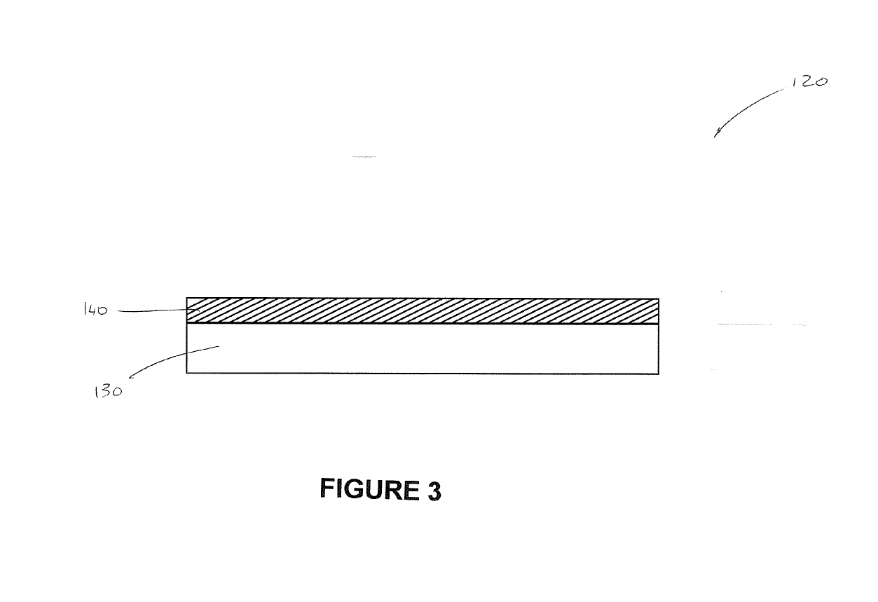

FIG. 4: shows a perspective view of a moulded tube.

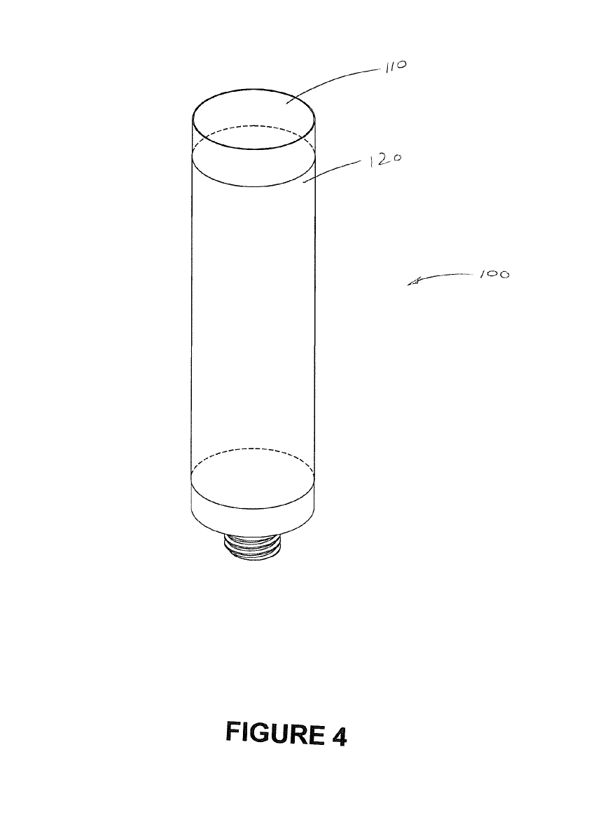

### DETAILED DESCRIPTION OF THE PREFERRED EMBODIMENT(S)

With reference to the above drawings, in which similar features are generally indicated by similar numerals, a moulded article according to a first aspect of the invention is generally indicated by the numeral 100.

In one embodiment now described, there is provided a moulded article in the form of a tube 100.

The tube 100 comprises a moulded body 110 and a label 120 that have been integrally formed with each other in a moulding process. The label 120 comprises a polymeric base layer 130 and a layer of metal 140. The layer of metal 140 is deposited on the polymeric base layer 130 by vacuum metalizing. This process will be described in more detail below.

In particular, it is envisaged that in a preferred embodiment the moulded body 110 will be integrally formed in an injection moulding process with the label 120 to form the moulded article 100.

The label 120 further comprises a layer of ink 150 extending over the layer of metal 140. In a preferred embodiment, the layer of ink 150 is printed, and preferably digitally printed on the layer of metal 140. It is envisaged that a layer of ink 150 will be digitally printed on the layer of metal 140 in a digitally controlled printing process.

In a preferred embodiment, the label 120 further comprises a pair of plastic laminate layers 160. The plastic laminate layers 160 extend to each side of the opposed major faces 132 of the combined polymeric base layer, layer of metal and layer of ink. In a preferred embodiment the proposed plastic laminate layers 160, the polymeric base layer 130, the layer of metal 140 and layer of ink 150 are preferably laminated together by a resin or bonding agent (not shown). Alternately, in another embodiment, it is envisaged that these layers could be laminated together by heat bonding or the like.

It is envisaged that preferably both of the plastic laminate layers will be composed of polypropylene (PP), although different embodiments are possible. In further examples, the plastic laminate layers could be composed of casted-polypropylene (CPP), polyethylene-teraphtalate (PET), or by biaxially orientated polypropylene (BOPP).

It is envisaged that the polymeric base layer 130 is preferably composed of polyethylene-teraphthalate (PET), although it is envisaged that it could be comprised of a number of other materials, such as polypropylene (PP), nylon, polyethylene (PE), or any other suitable material.

It is further envisaged that the metal used for the layer o metal is preferably aluminium, as this is a cost effective metal for vacuum metallisation. However, the metal used could also be one or more selected from copper, platinum, titanium, chromium, gold, lead, nickel, silver, tin, and tantalum.

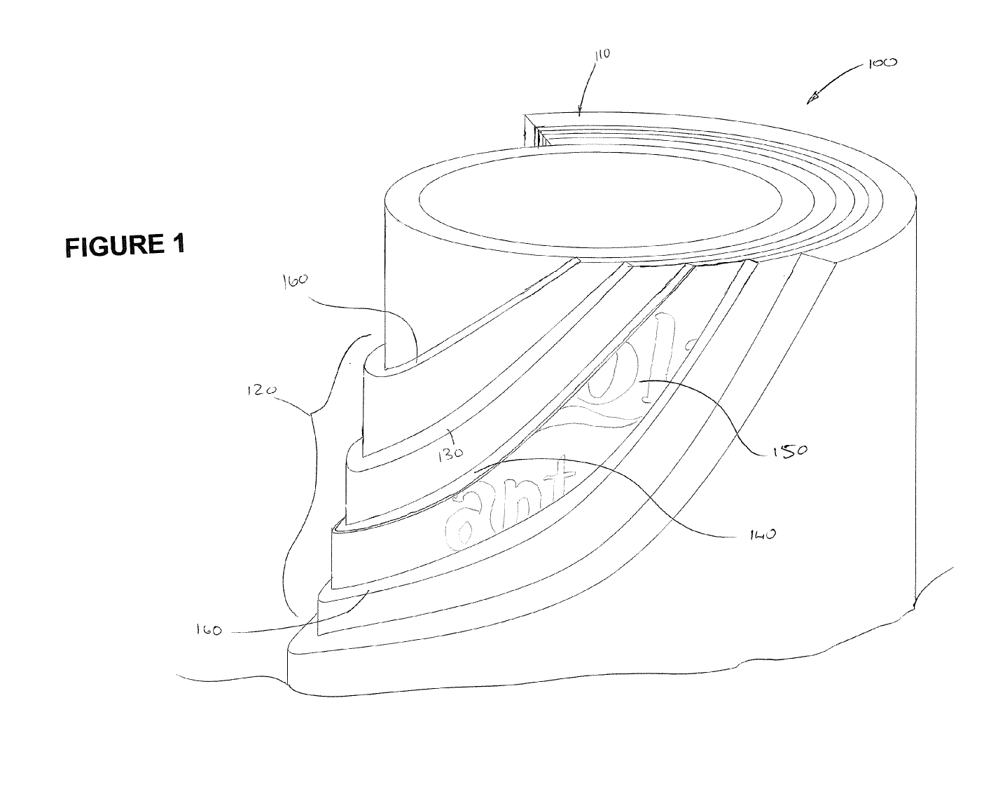

The moulded body 110 could be of a wide variety of configurations, and be used as a wide variety of moulded articles 100 together with the label 120. In a preferred embodiment, the moulded body will be moulded in a tube configuration, which when integrally formed with the label 120 creates the tube 100 shown in FIG. 1. It will be appreciated that the moulded body 110 could be of a wide variety of configurations besides a tube.

As shown in FIG. 1, the label itself is moulded within a moulded body (as the moulded body extends to either side of the label. However, it is envisaged that the label in another embodiment could, and preferably would be located to one side of the moulded body (yet still be integrally formed into it).

It is also envisaged that more than one label could also be integrally formed into the moulded body. It is also envisaged that labels of various shapes and configurations could be provided to provide different aesthetic effects while retaining at least some of the advantages, such as providing an increased barrier to oxygen.

In another aspect, there is further provided a method of producing the moulded article 100 above. In order to produce the moulded article 100, a label 120 is provided, the label 120 is comprised of a polymeric base layer 130 and a layer of metal 140 that has been deposited on the polymer based layer by vacuum metalizing.

In order to form the label, firstly a polymeric sheet (not shown) is provided. Then a metal is deposited on the polymeric sheet by a vacuum metallisation process to form a metallised sheet (not shown).

The step of the vacuum metalizing the layer of metal onto the polymeric sheet is carried out by inserting the polymer sheet into a vacuum chamber, reducing the pressure in the vacuum chamber to provide a reduced pressure environment and subjecting the polymer sheet to vaporise the metal for the vaporised metal to condensed on and attach to the polymer sheet, to form a metalized sheet. The vaporised metal is provided by vaporising metal for deposition on the polymer sheet. It is envisaged that the metalized sheet could then be cut to size, or used as it is as a label. Alternately, the polymeric sheet could be cut to size before the vacuum metallisation process.

In a preferred embodiment, it is envisaged that the layer of metal will also be printed on to provide colour, logos, wording or the like. Such printing is envisaged as being carried out by a digitally controlled printing process, although other manners of deposition of ink on the layer of metal are also envisaged, such as silk screening, painting, etc.

It is also envisaged that the; layer of ink may be covered by a layer of fastening matter for fastening the ink to the layer of metal. Such a fastening layer could be a varnish or any other suitable matter.

While it is envisaged that the bare polymeric base layer and metal layer, with or without an ink layer could be used as the label, in a preferred embodiment the polymeric base layer and layer of metal (with or without an ink layer) will be laminated together with a pair of plastic laminate layers, with the plastic laminate layers located distally or outside of the polymeric base layer and layer of metal over their opposed major faces to form a laminated label.

It is also envisaged that the polymeric sheet and or metallised sheet could be laminated with one or more plastic laminated layers before cutting to size as a label.

In order to laminate the polymeric sheet and/or metalized sheet with the plastic layers, is envisaged that the plastic layers will be bonded to the polymer sheet and/or the layer of metal by applying a resin or adhesive. One such adhesive that may be used is polyurethane. Polyurethane is typically comprised of two components, composed of isocyanate groups and hydroxyl groups respectively, which are combined to generate a stable polyurethane structure that can bind laminate layers together. Curing is regarded as being complete when all the isocyanate molecules are linked with the hydroxyl groups. Such curing is also typically carried out in a temperature controlled room, that is thermostatically controlled to a temperature between about 30 and 40 degrees Celsius. It is envisaged that other adhesives may also be used.

Alternately, it is envisaged that lamination could occur by heating of the various layers to bond with each other.

Where an adhesive is used to laminate the layers together, it is envisaged that the surface of the polymeric sheet and/or plastic layers could be treated to facilitate bonding of the adhesive. In one embodiment the surfaces of the polymer sheet and/or plastic layer could be treated by means of a Corona surface treatment. Such surface treatments are known and are not regarded as being within the scope of the present application.

While a pair of opposed plastic layers is envisaged in a preferred embodiment, it will be appreciated that this need not necessarily be the case. In another embodiment, a single plastic sheet could be provided on one of the sides of the polymeric sheet.

After lamination of the plastic laminate layers, it is envisaged that the label will need to be cured. Such curing time is envisaged as being anywhere between two and ten days, more preferably between two and five days, and most preferably about three days.

During this curing period, the laminated labels may be subjected to one or more of an increased temperature, a drying effect such as convection by blowing air over the laminated label, radiation, or any other suitable curing effect. In a preferred embodiment, the heating is provided by convection heating.

During manufacture of the label, careful control of the directional stresses in the label and its individual various layers is preferred, in order to prevent bending or curving of the label, which will make it difficult to handle and insert into a moulding cavity. For this reason, it is preferred that at least the plastic layers used for the label are symmetrical to either side of the metallised sheet, in order to balance out the directional stresses of each other. Further, the thickness of these materials must be carefully controlled to provide a thickness variance of less than 3%.

In another embodiment, it is envisaged that directional stresses in the label, or the manufactured label sheet (i.e. comprising the metallised layer with one or more of the plastic laminate layers, layer of ink and layer of varnish) that the labels are cut from can be controlled by tension control of the layers that are used to make up the label sheet. Tension control can be controlled in a layer or layers, by pulling it through a pulling device (not shown). Such a pulling device may be operated by servomotors controlled by a control system in response to detected tensions in a layer, for example detected by one or more tension sensors, in order to control tension in any of the layers being used, including but not limited to the plastic layers, polymeric layer metallised sheet and the laminated sheet. Such a pulling device could, for example, increase friction in a layer as it rolls along a production line.

It is envisaged that the step of tension control of any of the various layers making up the label sheet, as well as the label sheet itself can be provided during each step of the production process. It is known that presence of guide rollers will increase the friction acting on a sheet of material that is being unwound from a roller, and therefor increase the tension that sheet. In order to control the tensions of the various layers, and particularly with regard to the rewinding of rolls of processed (for example metallised, printed or varnished) layers, tension taper software may be used. Such tension taper software is known in the packaging industry and is not regarded as being within the scope of the present application.

Once the label is made, the label is inserted into a mould cavity (not shown) in a mould (not shown). In this regard it is envisaged that injection moulding would be the preferred moulding process, and accordingly the mould cavity would be of an injection moulding mould. It will be appreciated that a wide variety of articles, and particularly packaging articles, may be manufactured by injection moulding, and that the precise nature of the article moulded in the mould cavity.

Once the label is inserted into the injection mould cavity, the label is integrally formed with a moulded body to form a moulded article.

It is envisaged that the moulded article 100 so formed will preferably be a moulded tube, and that such a tube will preferably be used for packaging of matter that upgrades on exposure to oxygen.

It has been found by the applicant that the use of the vacuum metallisation process allows the moulded article so formed to have an increased barrier to oxygen, without the requirement for introducing ethylene vinyl alcohol polymer (EVOH).

Further, the moulded article so formed provides an aesthetically desirable metallic finish that will not fade, and is not expensive to produce.

It will be appreciated that other embodiments are possible in which have not been specifically described in the above description. For example, a single plastic laminate layer may be provided for lamination by bonding or heat treatment to either of the polymer sheet or the metal layer. The metal layer maybe printed on after lamination of a plastic laminate layer with the polymer sheet. Further, various forms of printing could be use to deposit ink on the layer of metal. Alternately, other methods of deposition of ink on the layer of metal could be used.

It will be appreciated that the polymeric base layer of the label need not be fully coated by the layer of metal. The layer of metal could be prevented from being deposited on the polymeric base layer by means of masking (for example by applying a masking layer) surfaces that do not require metal deposition. However, since the presence of the metal layer offers an increased barrier to oxygen, the deposition of metal over as large an area as possible is preferred.

Where in the foregoing description reference has been made to elements or integers having known equivalents, then such equivalents are included as if they were individually set forth.

Although the invention has been described by way of example and with reference to particular embodiments, it is to be understood that modifications and/or improvements may be made without departing from the scope or spirit of the invention.

In addition, where features or aspects of the invention are described in terms of Markush groups, those skilled in the art will recognise that the invention is also thereby described in terms of any individual member or subgroup of members of the Markush group.

1. A moulded article, said moulded article comprising
a. a moulded body; and
b. a label, said label comprising
i. a polymeric base layer, and
ii. a layer of metal that has been deposited on the polymeric base layer by vacuum metallising;
c. wherein said label is integrally formed with the moulded body.

2. A moulded article as claimed in claim 1, wherein the label comprises a layer of ink deposited on the layer of metal.

3. A moulded article as claimed in claim 2, wherein the layer of ink is printed on the layer of metal.

4. A moulded article as claimed in claim 2, wherein the layer of ink is digitally printed on the layer of metal in a digitally controlled printing process.

5. A moulded article as claimed in claim 2, wherein the label comprises a fastening layer for fastening the layer of ink to the layer of metal.

6. A moulded article as claimed in claim 5, wherein the fastening layer is a varnish layer.

7. A moulded article as claimed in claim 1, wherein the label further comprises at least one or more plastic laminate layers.

8. A moulded article as claimed in claim 7, wherein the label comprises a plastic laminate layer to either side of said polymeric base layer and layer of metal.

9. A moulded article as claimed in claim 8, wherein the plastic laminate layers are adhered to each other by an adhesive.

10. A moulded article as claimed in claim 8, wherein the adhesive is polyurethane.

11. A moulded article as claimed in claim 7, wherein at least one or more of the plastic laminate layers are composed of polypropylene

12. A moulded article as claimed in claim 7, wherein at least one or more of the plastic laminate layers are composed of one or more selected from:
a. casted polypropylene (CPP)
b. polyethylene terephthalate (PET)
c. biaxially oriented Polypropylene (BOPP).

13. A moulded article as claimed in claim 1, wherein the polymeric base layer is one or more selected from
a. polyethylene terephthalate (PET);
b. polypropylene (PP)
c. nylon;
d. polyethylene (PE); and
e. any other suitable material.

14. A moulded article as claimed in claim 1, wherein the layer of metal is composed from one or more selected from:
a. aluminium;
b. copper;
c. platinum;
d. titanium;
e. chromium;
f. titanium;
g. gold;
h. lead;
i. nickel;
j. silver;
k. tin; and
l. tantalum.

15. A moulded article as claimed in claim 1, wherein the moulded article is a tube.

16. A moulded article as claimed in claim 1, wherein the moulded article is a tube used for packaging.

17. A moulded article as claimed in claim 1, wherein the moulded article is a tube used for packaging of matter that degrades on exposure to oxygen.

18. A method of producing a moulded article, said method comprising the steps of
a. providing a label, said label comprising
i. at least a polymeric base layer, and
ii. a layer of metal that has been deposited on the polymer base layer by vacuum metallising;
b. inserting the label into a mould cavity in a mould; and
c. moulding a moulded body with the label.

19. The method as claimed in claim 18; wherein the mould is an injection moulding mould, and the step of moulding comprises the step of injecting molten thermoplastic into the mould cavity to mould the moulded body with the label.

20. The method as claimed in claim 18; wherein the step of providing a label comprises the step of providing a polymer sheet presenting at least one major surface.

21. The method as claimed in claim 20; wherein the method includes the step of depositing vaporised metal as a layer of metal on at least one major surface of the polymer sheet.

22. The method as claimed in claim 21; wherein the step of depositing vaporised metal on at least one major surface of the polymer sheet comprises the step of inserting the polymer sheet into a vacuum chamber.

23. The method as claimed in claim 22; wherein the step of depositing vaporised metal on at least one major surface of the polymer sheet comprises the step of subjecting the polymer sheet to a reduced-pressure environment.

24. The method as claimed in claim 21; wherein the step of depositing vaporised metal on at least one major surface of the polymer sheet comprises the step of vaporising metal for deposition on the polymer sheet.

25. The method as claimed in claim 21; wherein the step of depositing vaporised metal on at least one major surface of the polymer sheet comprises the step of subjecting the polymer sheet to the vaporised metal for the vaporised metal to condense on and attach to the polymer sheet, to form a metallised sheet.

26. The method as claimed in claim 18; wherein the step of providing a label comprises the step of depositing a layer of ink on the layer of metal printing on the layer of metal.

27. The method as claimed in claim 26; wherein the step of providing a label comprises the step of depositing a layer of ink on the layer of metal by printing on the layer of metal.

28. The method as claimed in claim 27; wherein the step of providing a label comprises the step of depositing a fastening layer on the layer of ink to fasten the layer of ink to the layer of metal.

29. The method as claimed in claim 28; wherein the fastening layer is a layer of varnish.

30. The method as claimed in claim 18; wherein the step of providing a label comprises the step of laminating at least the metallised sheet with one or more plastic layers.

31. The method as claimed in claim 30; wherein the step of laminating the metallised sheet with one or more plastic layers comprises the step of treating at least part of the surface of one or more selected from the plastic layers and the polymer sheet by means of a Corona surface treatment.

32. The method as claimed in claim 30; wherein the step of laminating the metallised sheet with at least one or more plastic layers comprises the steps of
a. providing a plastic laminate layer to either or both sides of one or more selected from the metallised sheet, layer of ink, and layer of varnish; and
b. laminating the layers so provided together.

33. The method as claimed in claim 30; wherein the step of laminating the metallised sheet with one or more plastic layers comprises the step of applying an adhesive for adhering at least one plastic laminate layer with one or more selected from another plastic laminate layer and the polymer sheet to form a laminated label.

34. The method as claimed in claim 33; wherein the adhesive is polyurethane.

35. The method as claimed in claim 30; wherein the step of laminating the metallised sheet with one or more plastic layers comprises the step of adhering at least one of the plastic laminate layers with the metallised sheet to form a laminated label.

36. The method as claimed in claim 30; wherein the method comprises the step of curing the laminated label.

37. The method as claimed in claim 36; wherein the step of curing the laminated labels comprises the step of subjecting the adhered label to one or more selected from:
a. an increased temperature;
b. a drying effect;
c. convection
d. radiation;
e. or any other suitable curing effect.

38. The method as claimed in claim 36; wherein the step of curing the adhered labels comprising curing the label for a period of between 1 and 10 days.

39. The method as claimed in claim 36; wherein the step of curing the adhered labels comprising curing the label for a period of between 2 and 5 days.

40. The method as claimed in claim 32; wherein at least one or more selected from the plastic layers, and the polymeric base layer, have a variation in thickness of less than 3%.

41. The method as claimed in claim 32; wherein at least one or more selected from the plastic layers and the polymeric base layer, have their internal stresses manipulated during at least part of the method.

42. The method as claimed in claim 32; wherein at least one or more selected from the plastic layers and the polymeric base layer, have their internal stresses manipulated during at least part of the method by means of a pulling device.

43. The method as claimed in claim 42; wherein the pulling device is controlled by a control system in response to tensions detected in a by a tension sensor.

44. The method as claimed in claim 32; wherein at least one or more selected from the plastic layers and the polymeric base layer, have their tension controlled throughout at least part of the method.

45. The method as claimed in claim 44; wherein the tension is controlled by a tension taper control system, in response to detected tensions in the said at least one or more selected from the plastic layers, and the polymeric base layer.

46. The method as claimed in claim 45; wherein the detected tensions are received from a tension sensor and controlled by a control system.

47. The method as claimed in claim 32; wherein at least one or more of the plastic laminate layers are composed of polypropylene

48. The method as claimed in claim 40; wherein the at least one or more of the plastic laminate layers are composed of one or more selected from:
a. casted polypropylene (CPP)
b. polyethylene terephthalate (PET)
c. biaxially oriented Polypropylene (BOPP).

49. The method as claimed in claim 18; wherein the polymeric base layer is one or more selected from
a. polyethylene terephthalate (PET);
b. polypropylene (PP)
c. nylon;
d. polyethylene (PE); and
e. any other suitable material.

50. The method as claimed in claim 18; wherein the layer of metal is composed of one or more selected from
a. aluminium;
b. copper;
c. platinum;
d. titanium;
e. chromium;
f. titanium;
g. gold;
h. lead;
i. nickel;
j. silver;
k. tin; and
l. tantalum.

51. A label for insertion into a mould for being integrally formed with a moulded body to form a moulded article, said moulded article comprising
a. a polymeric base layer; and
b. a layer of metal that has been deposited on the polymeric base layer by vacuum metallisation;
c. wherein the label is configured and adapted for being inserted into a mould cavity, and integrally formed with a moulded body to form a moulded article.

52. The label as claimed in claim 51; wherein the label comprises at least one plastic laminate layer.

53. The label as claimed in claim 52; wherein the label comprises a plurality of plastic laminate layers.

54. The label as claimed in claim 53; wherein the label comprises a plastic laminate layer on opposed sides of the layer of metal and the polymeric base layer

55. The label as claimed in claim 52; wherein the plastic laminate layers are adhered to at least one selected from the layer of metal and the polymeric base layer by an adhesive.

56. The label as claimed in claim 52; wherein the adhesive is a polyurethane.

57. The label as claimed in claim 51; wherein the label comprises a layer of ink that has been deposited on at least part of the layer of metal.

58. The label as claimed in claim 57; wherein the label comprises a fastening layer for fastening the layer of ink to the layer of metal.

59. The label as claimed in claim 58; wherein the fastening layer is a varnish layer.

60. The label as claimed in claim 52; wherein at least one or more plastic laminate layer is composed of polypropylene

61. The label as claimed in claim 52; wherein at least one or more plastic laminate layer is composed of one or more selected from:
a. casted polypropylene (CPP)
b. polyethylene terephthalate (PET)
c. biaxially oriented Polypropylene (BOPP).

62. The label as claimed in claim 51; wherein the polymeric base layer is composed of one or more selected from
a. polyethylene terephthalate (PET);
b. polypropylene (PP)
c. nylon;
d. polyethylene (PE); and
e. any other suitable material.

63. The label as claimed in claim 51; wherein the metal of the metal layer is one or more selected from
a. aluminium;
b. copper;
c. platinum;
d. titanium;
e. chromium;
f. titanium;
g. gold;
h. lead;
i. nickel;
j. silver;
k. tin; and
l. tantalum.

64. The label as claimed in claim 51; wherein the mould cavity is for is an injection moulding mould.
